(19) United States
(12) Patent Application Publication
(10) Pub. No.: US 2021/0110878 A1
(43) Pub. Date: Apr. 15, 2021

(54) MULTI-LAYER ONE TIME PROGRAMMABLE PERMANENT MEMORY AND PREPARATION METHOD THEREOF

(71) Applicant: Zezhong Peng, Chengdu (CN)

(72) Inventor: Zezhong Peng, Chengdu (CN)

(21) Appl. No.: 16/601,521

(22) Filed: Oct. 14, 2019

(51) Int. Cl. G11C 17/16; H01L 27/112; G11C 17/18; H01L 23/522; H01L 23/528; H01L 23/525; H01L 21/02; H01L 21/3213

(52) U.S. Cl. CPC G11C 17/16; H01L 27/11206; G11C 17/18; H01L 23/5226; H01L 21/32133; H01L 23/5252; H01L 21/02532; H01L 21/02595; H01L 23/528

(57) ABSTRACT

A multi-layer one time programmable permanent memory unit (MLOTPPMU) and methods for manufacturing the MLOTPPMU are provided. The MLOTPPMU includes at least two one time programmable permanent memory (OTPPM) modules and a thin insulating dielectric material (IDM). Each OTPPM module includes M rows and N columns made of counter doped semiconductor materials. The IDM is positioned at intersections of the M rows and the N columns of each OTPPM module and on a top surface or a bottom surface of each M row and each N column of each OTPPM module. The MLOTPPMU is manufactured using a planar deposition process and semiconductor material etching or by constructing trenches in an IDM and filling the trenches with counter doped semiconductor materials. Symmetrically stacking the OTPPM modules in a bottom up direction vertically to form the MLOTPPMU results in a substantial increase in permanent OTP memory density at substantially low processing costs.

### CROSS-REFERENCE TO RELATED APPLICATIONS

This application is a national stage application of the Patent Cooperation Treaty (PCT) international application titled “Multi-Layer One-Time Programmable Permanent Memory Unit And Preparation Method Therefor”, international application number PCT/CN2017/099271, filed in the State Intellectual Property Office of China on Aug. 28, 2017, which claims priority to and the benefit of the patent application titled “Multi-Layer One-Time Programmable Permanent Memory Unit And Preparation Method Therefor”, patent application number 201710078729.4, filed in the State Intellectual Property Office of China on Feb. 14, 2017. The specifications of the above referenced patent applications are incorporated herein by reference in their entirety.

### BACKGROUND

The memory device and methods of manufacture disclosed herein, in general, relate to mass data storage. More particularly, the memory device and methods of manufacture disclosed herein relate to one time programmable (OTP) permanent memory technology.

Digital memory storage technology comprising, for example, an erasable programmable read-only memory (EPROM), an electrically erasable programmable read-only memory (EEPROM), a flash memory, a NAND flash memory, magnetic hard disks, compact discs (CDs), digital versatile discs (DVDs), the Blue-ray Disc® of Blu-ray Disc Association, etc., has been developed and widely used for storing data for more than 50 years. However, the lifetime of storage media is typically less than 5 years to 10 years. Anti-fuse memory technology developed for big data storage may be inadequate for mass data storage as the anti-fuse memory technology is very expensive and has low memory density.

Hence, there is a long felt need for a substantially high density and low cost multi-layer one time programmable (OTP) permanent memory unit for mass data storage, which can store data over a substantial period of time in severe environmental conditions. Moreover, there is a long felt need for a method for manufacturing a multi-layer OTP permanent memory unit by stacking layers of counter doped semiconductor materials, for example, polycrystalline silicon, single crystal silicon, etc., on both sides of a thin dielectric layer to produce anti-fuse programmable diode memory arrays.

### SUMMARY OF THE INVENTION

This summary is provided to introduce a selection of concepts in a simplified form that are further disclosed in the detailed description of the invention. This summary is not intended to determine the scope of the claimed subject matter.

The memory device disclosed herein addresses the above recited need for a substantially high density, reliable, and low cost multi-layer one time programmable (OTP) permanent memory unit for mass data storage, which can store data over a substantial period of time in severe environmental conditions. Moreover, the methods disclosed herein address the above recited need for manufacturing a multi-layer OTP permanent memory unit by stacking layers of counter doped semiconductor materials, for example, polycrystalline silicon, single crystal silicon, etc., on both sides of a thin dielectric layer to produce anti-fuse programmable diode memory arrays.

The multi-layer one time programmable (OTP) permanent memory unit disclosed herein comprises at least two OTP permanent memory modules stacked in layers one above another, and a thin insulating dielectric material. Each of the OTP permanent memory modules comprises M rows and N columns made of counter doped semiconductor materials, where M and N are positive integers greater than one. In an embodiment, each of the one time programmable (OTP) permanent memory modules of the multi-layer OTP permanent memory unit disclosed herein comprises M rows and N columns made of conductors. The thin insulating dielectric material is positioned at intersections of the M rows and the N columns of each of the OTP permanent memory modules and on a top surface or a bottom surface of each of the M rows and each of the N columns of each of the OTP permanent memory modules. Furthermore, the thin insulating dielectric material is positioned between the M rows and the N columns of each of the OTP permanent memory modules. The M rows of each of the OTP permanent memory modules is made of a p-type semiconductor material or an n-type semiconductor material, while the N columns of each of the OTP permanent memory modules is made of a counter doped semiconductor material. That is, if the M rows of each of the OTP permanent memory modules is made of a p-type semiconductor material, the N columns of each of the OTP permanent memory modules is made of an n-type semiconductor material, and vice versa.

Each of the one time programmable (OTP) permanent memory modules is stacked in a bottom up direction by connecting the intersections of the M rows and the N columns of each of the OTP permanent memory modules with intersections between the OTP permanent memory modules. The M rows of each of the OTP permanent memory modules are positioned on a top or a bottom of the N columns. The multi-layer OTP permanent memory unit disclosed herein further comprises multiple OTP permanent memory units formed at the intersections of the M rows and the N columns of each of the OTP permanent memory modules and the intersections between the OTP permanent memory modules. Each of the OTP permanent memory units comprises a p-type semiconductor area, an n-type semiconductor area, and a thin insulating dielectric area positioned between the p-type semiconductor area and the n-type semiconductor area. Each of the OTP permanent memory units further comprises at least two connecting terminals positioned on the p-type semiconductor area and the n-type semiconductor area of each of the OTP permanent memory units. The connecting terminals of each of the OTP permanent memory units are connected to each other using conducting vias made of, for example, a metal, or a doped polycrystalline silicon, or other conducting materials. The thickness of the thin insulating dielectric material forming the thin insulating dielectric area of each of the OTP permanent memory units has a preset value corresponding to a breakdown voltage of each of the OTP permanent memory units. The thin insulating dielectric material, for example, silicon dioxide (SiO) of thickness of about 0.5 nanometers (nm) to about 4 nm has a breakdown voltage of, for example, about 3 volts (V) to about 10V.

Also, disclosed herein is a method for manufacturing a multi-layer one time programmable (OTP) permanent memory unit using planar deposition and etching semiconductor materials, for example, polycrystalline silicon or silicon. The method disclosed herein comprises setting semiconductor materials on a top planar surface of a wafer comprising finished memory peripheral circuits, using a deposition process or an epitaxy process; counter doping the set semiconductor materials with p-type or n-type dopants using an ion implantation process or a diffusion process; creating semiconductor material bars from the counter doped semiconductor materials to form M rows or N columns of an OTP permanent memory module made of the counter doped semiconductor materials by removing an excess portion of the counter doped semiconductor materials using a photolithographic masking process and an etching process; filling the created semiconductor material bars that forms the M rows or the N columns of the OTP permanent memory module with an insulating dielectric material using a planarization process; removing an excess of the insulating dielectric material in the filled semiconductor material bars that form the M rows or the N columns of the OTP permanent memory module, that overflows the created semiconductor material bars using a chemical and mechanical polishing process; creating a thin insulating dielectric film, for example, of silicon dioxide (SiO₂), on the filled semiconductor material bars that form the M rows or the N columns of the OTP permanent memory module using a thermal oxidation process, a low temperature chemical vapor deposition process, or an atomic layer deposition (ALD) process; and repeating the above method a predetermined number of times for producing the multi-layer OTP permanent memory unit by symmetrically stacking each OTP permanent memory module that is created each time in a bottom up direction vertically.

Also, disclosed herein is another method for manufacturing a multi-layer one time programmable (OTP) permanent memory unit. The method disclosed herein comprises depositing a thick layer of an insulating dielectric material on a top planar surface of a wafer comprising finished memory peripheral circuits; constructing trenches on the deposited thick layer of the insulating dielectric material using a masked etching process, for example, plasma ion etching, for positioning rows or columns of an OTP permanent memory module; depositing semiconductor materials on the constructed trenches; counter doping the deposited semiconductor materials with p-type or n-type dopants using a diffusion process or an ion implantation process; forming M rows or N columns of the OTP permanent memory module from the counter doped semiconductor materials by removing an excess of the deposited semiconductor materials from the counter doped semiconductor materials using a common planarization process; creating a thin insulating dielectric film on the M rows or the N columns of the OTP permanent memory module using a thermal oxidation process, or a thermal deposition process, or an atomic layer deposition (ALD) process; and repeating the above method a predetermined number of times for producing the multi-layer OTP permanent memory unit by symmetrically stacking each OTP permanent memory module that is created each time in a bottom up direction vertically. The thin insulating dielectric film on the M rows and the N columns of the OTP permanent memory module serves as a programmable dielectric material.

The methods disclosed herein use, for example, a poly/thin oxide/poly anti-fuse mechanism to form the multi-layer one time programmable (OTP) permanent memory unit, where “poly” refers to polycrystalline silicon and thin oxide is a thin insulating dielectric material. The methods disclosed herein stack, for example, p-poly/thin oxide/n-poly/thin oxide/p-poly/thin oxide to form a vertical multi-layer high density memory, where “p-poly” refers to positive doped polycrystalline silicon and “n-poly” refers to negative doped polycrystalline silicon. In an embodiment, the doped polycrystalline silicon is replaced by silicon (Si). In an embodiment, the thin oxide is thermally grown from a polycrystalline silicon layer created at the bottom or by deposition. The thin oxide can also be replaced by other dielectric films, for example, nitrides or a combination of oxides and nitrides. Each layer of the multi-layer OTP permanent memory unit forms programmable p-n junction diodes with its bottom and top counter doped poly or Si layer to significantly increase stacking memory density at a low cost. Multi-layer memory arrays in the multi-layer OTP permanent memory unit comprise programmable diodes. N-channel metal oxide semiconductor (NMOS) transistors and p-channel metal oxide semiconductor (PMOS) transistors are used for programming, sensing, and decoding circuits. For example, a programmable diode defined by p-poly/thin oxide/n-poly prevents reverse current from biased unselected rows and unselected columns. P-poly and n-poly lines are also used as row and column line connections, thereby precluding the need for an expensive metal line strip on top of each poly line to increase memory density.

The methods disclosed herein produce a high density multi-layer one time programmable (OTP) permanent memory unit with low cost OTP permanent memory units. The produced multi-layer OTP permanent memory unit has a high memory density. For example, the methods disclosed herein produce a 10 terabyte (TB) multi-layer OTP permanent memory unit on a chip having an area of 25 millimeter (mm) by 25 mm using a 10 nanometer (nm) silicon process. The multi-layer OTP permanent memory unit produced has very small form factors and permanent data retention life time of, for example, greater than 100 years.

In one or more embodiments, related systems comprise circuitry for affecting the methods disclosed herein. The circuitry can be any combination of hardware and/or firmware configured to effect the methods disclosed herein depending upon the design choices of a system designer. Also, various structural elements can be employed depending on the design choices of the system designer.

### BRIEF DESCRIPTION OF THE DRAWINGS

The foregoing summary, as well as the following detailed description of the invention, is better understood when read in conjunction with the appended drawings. For the purpose of illustrating the invention, exemplary constructions of the invention are shown in the drawings. However, the invention is not limited to the specific methods and components disclosed herein. The description of a method step or a component referenced by a numeral in a drawing is applicable to the description of that method step or component shown by that same numeral in any subsequent drawing herein.

FIG. 1 exemplarily illustrates a perspective view of a single one time programmable permanent memory module of a multi-layer one time programmable permanent memory unit.

FIG. 2 exemplarily illustrates a perspective view of a multi-layer one time programmable permanent memory unit formed by stacking two one time programmable permanent memory modules in layers one above another.

FIG. 3 exemplarily illustrates a block diagram of a one time programmable permanent memory unit.

FIG. 4 exemplarily illustrates a circuit diagram of the one time programmable permanent memory unit shown in FIG. 3.

FIG. 5 exemplarily illustrates a perspective view of an embodiment of a single one time programmable permanent memory module with one time programmable memory units formed at intersections of rows and columns of the one time programmable permanent memory module.

FIG. 6 exemplarily illustrates the one time programmable memory units formed at the intersections of the rows and the columns of the one time programmable permanent memory module shown in FIG. 5.

FIG. 7 exemplarily illustrates a partial front elevation view of the multi-layer one time programmable permanent memory unit.

FIG. 8 exemplarily illustrates a circuit diagram of a memory array circuit of the multi-layer one time programmable permanent memory unit shown in FIG. 7.

FIG. 9 exemplarily illustrates a partial side elevation view of an embodiment of the multi-layer one time programmable permanent memory unit.

FIG. 10 exemplarily illustrates a circuit diagram of a memory array circuit of the embodiment of the multi-layer one time programmable permanent memory unit shown in FIG. 9.

FIG. 11 exemplarily illustrates a top plan view of the multi-layer one time programmable permanent memory unit.

FIG. 12 exemplarily illustrates a front elevation view showing multiple one time programmable permanent memory modules stacked in a bottom up direction to form the multi-layer one time programmable permanent memory unit.

FIG. 13 exemplarily illustrates a side elevation view showing an embodiment of one time programmable permanent memory modules stacked in a bottom up direction to form the multi-layer one time programmable permanent memory unit.

FIG. 14 exemplarily illustrates a top plan view of an embodiment showing multiple one time programmable permanent memory modules positioned adjacent to each other in a single layer, where rows and columns made of counter doped semiconductor materials are interconnected using conducting vias.

FIG. 15 exemplarily illustrates a cross-sectional view of the multi-layer one time programmable permanent memory unit along with a row direction, showing interconnections of rows of doped semiconductor materials of different layers stacked to form the multi-layer one time programmable permanent memory unit.

FIG. 16 exemplarily illustrates a cross-sectional view of the multi-layer one time programmable permanent memory unit along with a column direction, showing interconnections of columns of counter doped semiconductor materials of different layers stacked to form the multi-layer one time programmable permanent memory unit.

FIGS. 17-19 exemplarily illustrates circuit diagrams of memory array circuits of embodiments of multiple one time programmable permanent memory modules stacked to form the multi-layer one time programmable permanent memory unit.

FIG. 20 illustrates a method for manufacturing a multi-layer one time programmable permanent memory unit using a planar deposition process and a semiconductor material etching process.

FIG. 21 illustrates a method for manufacturing a multi-layer one time programmable permanent memory unit by constructing trenches in an insulating dielectric material and filling the trenches with semiconductor materials.

FIG. 22 is a partial schematic view of a Schottky contact embodiment.

### DETAILED DESCRIPTION OF THE INVENTION

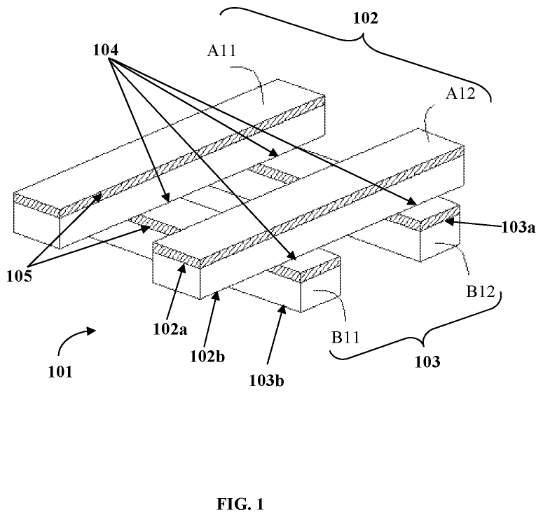

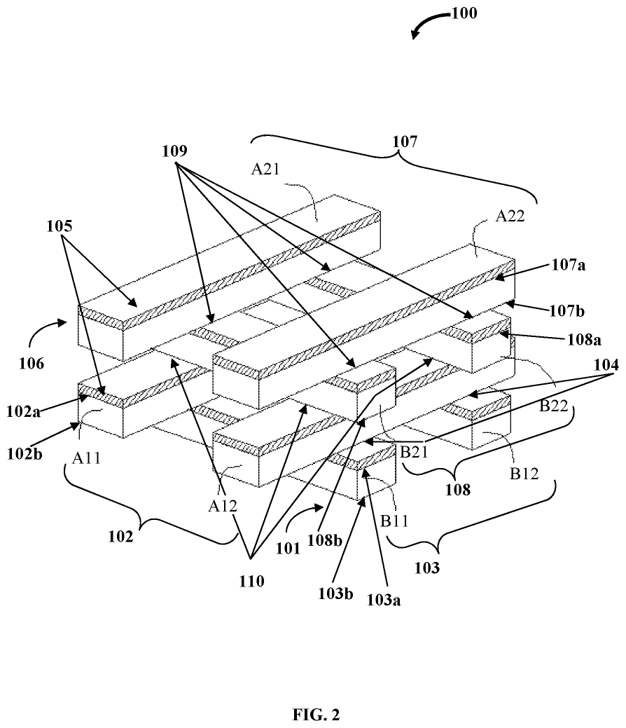

FIG. 1 exemplarily illustrates a perspective view of a single one time programmable (OTP) permanent memory module 101 of a multi-layer OTP permanent memory unit 100 exemplarily illustrated in FIG. 2. The OTP permanent memory unit 100 disclosed herein is a vertical, high density, high reliability and low cost permanent OTP memory. The single OTP permanent memory module 101 exemplarily illustrated in FIG. 1, constitutes one layer of the multi-layer OTP permanent memory unit 100. The OTP permanent memory module 101 comprises M rows 102 and N columns 103 made of counter doped semiconductor materials, where M and N are positive integers greater than one. For example, the OTP permanent memory module 101 exemplarily illustrated in FIG. 1, comprises at least two rows 102 and at least two columns 103. The OTP permanent memory module 101 comprises a first row A11 and a second row A12 positioned on top of a first column B11 and a second column B12 as exemplarily illustrated in FIG. 1. M and N can be any integer between 1 to 1024*1204. The rows 102 are made of a p-type semiconductor material or an n-type semiconductor material, and the columns 103 are made of a counter one of the p-type semiconductor material and the n-type semiconductor material. For example, if the first row A11 and the second row A12 are made up of a p-type semiconductor material, then the first column B11 and the second column B12 are made up of an n-type semiconductor material, and vice versa.

The rows 102 and the columns 103 of the one time programmable (OTP) permanent memory module 101 are arranged in straight lines such that the rows 102 and the columns 103 are perpendicularly intersecting each other to obtain optimal results. In an embodiment, the rows 102 and the columns 103 are positioned in different configurations, for example, as non-straight lines, in a non-strictly perpendicular direction, or in a curved manner, etc. The different configurations of the rows 102 and the columns 103 produce different results. The rows 102 can be referred as “word lines” and the columns 103 can be referred as “bit lines”. Alternatively, the rows 102 can be referred as “bit lines” and the columns 103 can be referred as “word lines”.

The one time programmable (OTP) permanent memory module 101 further comprises a thin insulating dielectric material 105, for example, silicon dioxide (SiO₂), positioned on top surfaces 102a and 103a of the rows 102 and the columns 103 respectively. In an embodiment (not shown), the insulating dielectric material 105, for example, SiO₂, is positioned on bottom surfaces 102b and 103b of the rows 102 and the columns 103 respectively. The insulating dielectric material 105 is illustrated as shaded regions in FIG. 1. The excess insulating dielectric material 105 falling outside the intersections 104 of the rows 102 and the columns 103 is removed using an etching process, and thereafter the rows 102 and the columns 103 are filled with the insulating dielectric material 105 during a planarization process. The filled insulating dielectric material 105 is exemplarily illustrated as an unshaded region on top surfaces 102a and 103a of the shaded regions in FIG. 1.

FIG. 2 exemplarily illustrates a perspective view of a multi-layer one time programmable (OTP) permanent memory unit 100 formed by stacking two OTP permanent memory modules 101 and 106 in layers one above another. The multi-layer OTP permanent memory unit 100 disclosed herein comprises at least two OTP permanent memory modules 101 and 106 stacked in layers one above another and a thin insulating dielectric material 105. Each of the OTP permanent memory modules 101 and 106 comprises M rows 102 and 107 respectively, and N columns 103 and 108 respectively, made of counter doped semiconductor materials, where M and N are positive integers greater than one. For example, a first OTP permanent memory module 101 comprises 2 rows 102 and 2 columns 103 made of counter doped semiconductor materials, and a second OTP permanent memory module 106 comprises 2 rows 107 and 2 columns 108 respectively, made of counter doped semiconductor materials. The rows 102 and 107 of the OTP permanent memory modules 101 and 106 respectively, are positioned on the top of the columns 103 and 108 respectively, as exemplarily illustrated in FIG. 2. In an embodiment (not shown), the rows 102 and 107 of the OTP permanent memory modules 101 and 106 respectively, are positioned on the bottom of the columns 103 and 108 respectively. To obtain optimal data storage, the rows 102 and 107 and the columns 103 and 108 of the OTP permanent memory modules 101 and 106 respectively, are arranged as straight lines and placed perpendicular to each other.

Each of the one time programmable (OTP) permanent memory modules 101 and 106 is stacked in a bottom up direction by connecting the intersections 104 and 109 of the rows 102 and 107 and the columns 103 and 108 of the OTP permanent memory modules 101 and 106 respectively, with intersections 110 between the OTP permanent memory modules 101 and 106. For example, a second OTP permanent memory module 106 comprising a first row A21, a second row A22, a first column B21, and a second column B22 is stacked on top of a first OTP permanent memory module 101 comprising a first row A11, a second row A12, a first column B11, and a second column B12 as exemplarily illustrated in FIG. 2. The insulating dielectric material 105 is positioned at intersections 104 and 109 of and between the rows 102 and 107 and the columns 103 and 108 of the OTP permanent memory modules 101 and 106 respectively, and on top surfaces 102a and 107a of the M rows 102 and 107 respectively, and on top surfaces 103a and 108a of the N columns 103 and 108 respectively, of the OTP permanent memory modules 101 and 106 respectively. In an embodiment (not shown), the insulating dielectric material 105 is positioned at the intersections 104 and 109 of and between the rows 102 and 107 and the columns 103 and 108 of the OTP permanent memory modules 101 and 106 respectively, and on bottom surfaces 102b and 107b of the M rows 102 and 107 respectively, and on bottom surfaces 103b and 108b of the N columns 103 and 108 respectively, of the OTP permanent memory modules 101 and 106 respectively.

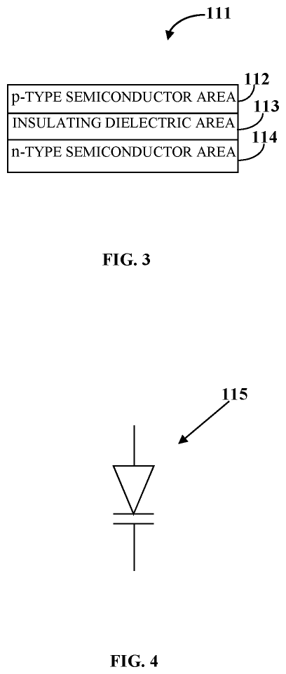

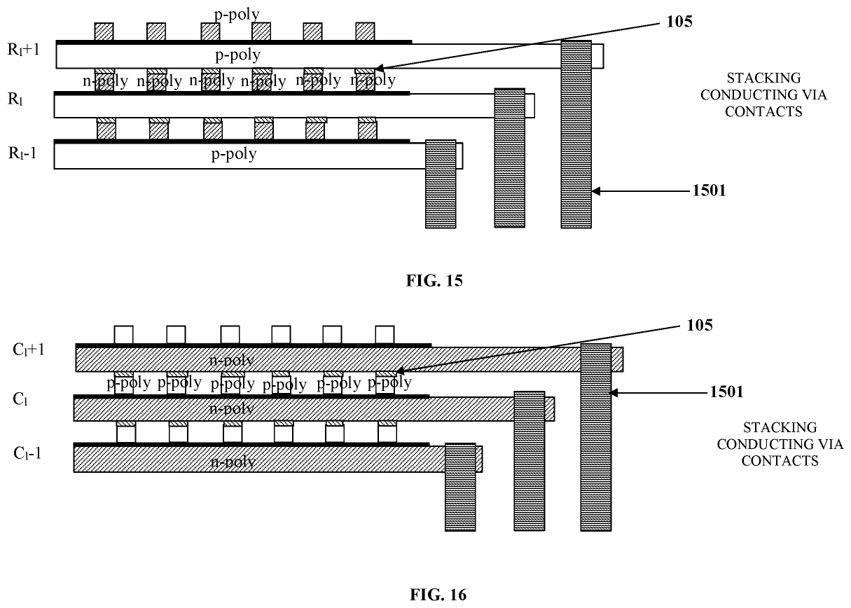

The intersections 104 and 109 of the rows 102 and 107 and the columns 103 and 108 of the one time programmable (OTP) permanent memory modules 101 and 106 respectively, and intersections 110 between the OTP permanent memory modules 101 and 106 of the multi-layer OTP permanent memory unit 100 form multiple OTP permanent memory units. The OTP permanent memory units are located at the intersections 104 A11-B11, A11-B12, A12-B12, and A12-B11 respectively, exemplarily illustrated in FIG. 1. Furthermore, OTP permanent memory units are located at the intersections 109 and 110 A11-B21, A11-B22, A12-B21, A12-B22, A21-B21, A21-B22, A22-B22, and A22-B21 as exemplarily illustrated in FIG. 2. Each of the OTP permanent memory modules 101 and 106 comprises four OTP permanent memory units. For example, the OTP permanent memory module 101 comprises the four OTP permanent memory units 111a, 111b, 111c, and 111d exemplarily illustrated in FIG. 6. The multi-layer OTP permanent memory unit 100 with at least two OTP permanent memory modules 101 and 106 comprises twelve OTP permanent memory units. Each of the OTP permanent memory units comprises a p-type semiconductor area 112, an n-type semiconductor area 114, and a thin insulating dielectric area 113 positioned between the p-type semiconductor area 112 and the n-type semiconductor area 114 as exemplarily illustrated in FIG. 3. The thin insulating dielectric area 113 separates the p-type semiconductor area 112 and the n-type semiconductor area 114. Each of the OTP permanent memory units further comprises at least two connecting terminals, for example, 116a and 116b exemplarily illustrated in FIG. 6, positioned on the p-type semiconductor area 112 and the n-type semiconductor area 114 of each of the OTP permanent memory units. The connecting terminals, for example, 116a and 116b of each of the OTP permanent memory units are connected to each other using conducting vias 1501, for example, metal vias exemplarily illustrated in FIGS. 15-16. Consider an example where the rows A11, A12, and A21, A22 of the multi-layer OTP permanent memory unit 100 exemplarily illustrated in FIG. 2, are made of a p-type semiconductor material positioned on top of the columns B11, B12, and B21, B22 respectively, made of an n-type semiconductor material. The p-type semiconductor material of the rows A11, A12, A21, and A22 and the n-type semiconductor material of the columns B11, B12, B21, and B22 form the p-type semiconductor area 112 and the n-type semiconductor area 114 of each of the OTP permanent memory units respectively.

FIG. 3 exemplarily illustrates a block diagram of a one time programmable (OTP) permanent memory unit 111. The OTP memory unit 111 comprises a p-type semiconductor area 112, an n-type semiconductor area 114, and a thin insulating dielectric area 113 positioned between the p-type semiconductor area 112 and the n-type semiconductor area 114. Thickness of the thin insulating dielectric material 105 forming the thin insulating dielectric area 113 of each OTP permanent memory unit 111 has a preset value corresponding to a breakdown voltage of each OTP permanent memory unit 111. As a thick dielectric material needs a higher programming voltage, and a substantially thin dielectric material causes unwanted breakdown and leakage, the thickness of the thin insulating dielectric material 105 forming the thin insulating dielectric area 113 of each OTP permanent memory unit 111 is set to be suitable for a proper programming voltage and avoidance of leakage. The insulating dielectric material 105, for example, a silicon dioxide (SiO2) has a thickness of about 0.5 nanometer (nm) to about 4 nm, and silicon nitride (Si3N4) has a thickness greater than 4 nm. In an embodiment, other insulating dielectric materials having a thickness of less than about 0.5 nm are used. The orientation of the OTP permanent memory unit 111 can be interchanged by interchanging the position of the p-type semiconductor area 112 and the n-type semiconductor area 114.

FIG. 4 exemplarily illustrates a circuit diagram 115 of the one time programmable (OTP) permanent memory unit 111 shown in FIG. 3. The OTP permanent memory unit 111 is electrically represented as a diode in serial connection with a programmable anti-fuse capacitor. The direction of the OTP permanent memory unit 111 exemplarily illustrated in FIG. 4, corresponds to the arrangement of the p-type semiconductor area 112, the insulating dielectric area 113, and the n-type semiconductor area 114 in the OTP permanent memory unit 111 exemplarily illustrated in FIG. 3. The OTP permanent memory unit 111 prevents flow of reverse currents from other programmed bits.

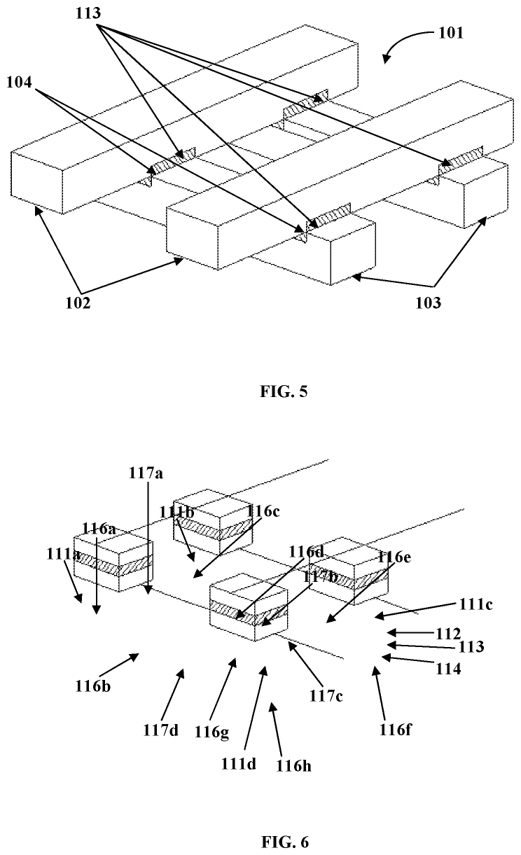

FIG. 5 exemplarily illustrates a perspective view of an embodiment of a single one time programmable (OTP) permanent memory module 101 with OTP permanent memory units 111a, 111b, 111c, and 111d exemplarily illustrated in FIG. 6, formed at intersections 104 of rows 102 and columns 103 of the OTP permanent memory module 101. In this embodiment, the OTP permanent memory module 101 comprises M rows 102 and N columns 103 made of conductors, wherein M and N are positive integers greater than one. The conductors are, for example, a metalized silicide or a doped polycide, or other conducting materials. Polycide is a combination of polycrystalline silicon and silicide. In an example, the OTP permanent memory module 101 exemplarily illustrated in FIG. 5, comprises at least two rows 102 and at least two columns 103. The intersections 104 of the rows 102 and the columns 103 of the OTP permanent memory module 101 create multiple OTP permanent memory units 111a, 111b, 111c, and 111d as exemplarily illustrated in FIG. 6 and as disclosed in the detailed description of FIG. 2. The shaded regions at the intersections 104 of the rows 102 and the columns 103 of the OTP permanent memory module 101 exemplarily illustrated FIG. 5, represent the insulating dielectric areas 113 of each of the OTP permanent memory units 111a, 111b, 111c, and 111d.

FIG. 6 exemplarily illustrates the one time programmable (OTP) permanent memory units 111a, 111b, 111c, and 111d formed at the intersections 104 of the rows 102 and the columns 103 of the OTP permanent memory module 101 shown in FIG. 5. The OTP permanent memory module 101 comprising at least two rows 102 and two columns 103 made of conductors form four OTP permanent memory units 111a, 111b, 111c, and 111d at four intersections 104 exemplarily illustrated as independent blocks in FIG. 6. Top connecting terminals 116a, 116c and 116e, 116g of the four OTP permanent memory units 111a, 111b, 111c, and 111d respectively, are connected by two row lines 117a and 117c respectively. Bottom connecting terminals 116b, 116h and 116d, 116f of the four OTP permanent memory units 111a, 111b, 111c, and 111d respectively, are connected by two column lines 117d and 117b respectively.

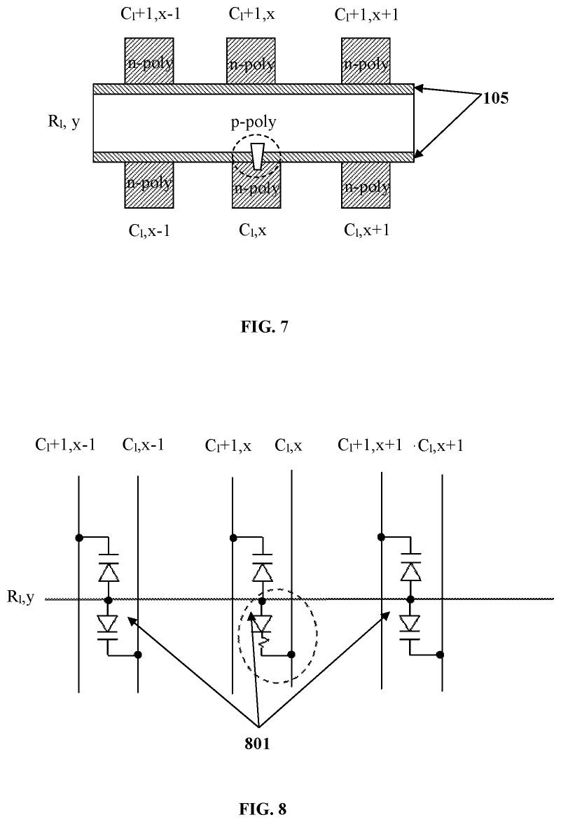

In FIGS. 7-13 and FIGS. 15-19 disclosed below, “l”, that is, the lower case of L, indicates a number of a layer or a number of a one time programmable (OTP) permanent memory module, for example, 101 or 106 constituting the multi-layer OTP permanent memory unit 100 exemplarily illustrated in FIG. 2, and can be any integer between 1 to 1024; “R” indicates a row line of a layer or an OTP permanent memory module, for example, 101 or 106; “C” indicates a column line; “x” indicates a column line number; and “y” indicates a row line number.

FIG. 7 exemplarily illustrates a partial front elevation view of the multi-layer one time programmable (OTP) permanent memory unit 100 exemplarily illustrated in FIG. 2. As exemplarily illustrated in FIG. 7, row (Rₗ,y) of a layer is positioned on top of columns of the layer represented as (Cₗ,x−1), (Cₗ,x), and (Cₗ,x+1). (Cₗ,x) indicates a column of a layer one (1) whose index is x. Similarly, (Cₗ,x−1) and (Cₗ,x+1) are two columns on either side of the column (Cₗ,x). As exemplarily illustrated in FIG. 7, the rows of the layer are made of a p-type semiconductor material, for example, positive doped polycrystalline silicon (p-poly), while the columns of the layer are made of an n-type semiconductor material, for example, negative doped polycrystalline silicon (n-poly). The rows of the layer (Rₗ,y) intersect the columns (Cₗ₊₁,x−1), (Cₗ,x−1), (Cₗ₊₁,x), (Cₗ,x), (Cₗ₊₁,x+1), and (Cₗ,x+1) with the insulating dielectric material 105 at the intersections. On applying a programming voltage, the insulating dielectric material 105 at the intersections of the row (Rₗ,y) and the column (Cₗ,x) breaks down and forms p-n junction diodes at the intersections of the rows and columns of the layer. The p-poly material and the n-poly material diffuse through the broken insulating dielectric material 105 to form the p-n junction diodes. The distance between adjacent rows and adjacent columns is maintained at a minimum in process design rules to achieve a substantially better memory density. To achieve a better memory density, the distances between adjacent rows and adjacent columns in each layer are made optimal for larger than minimum process design rules.

FIG. 8 exemplarily illustrates a circuit diagram of a memory array circuit of the multi-layer one time programmable (OTP) permanent memory unit shown in FIG. 7. The circuit diagram shows p-n junction diodes 801 formed at the intersections of each of the columns, (Cₗ₊₁,x−1), (Cₗ,x−1), (Cₗ₊₁,x), (Cₗ,x), (Cₗ₊₁,x+1), and (Cₗ,x+1) with the row (Rₗ,y) due to breaking of the insulating dielectric material 105 at the intersections as disclosed in the detailed description of FIG. 7.

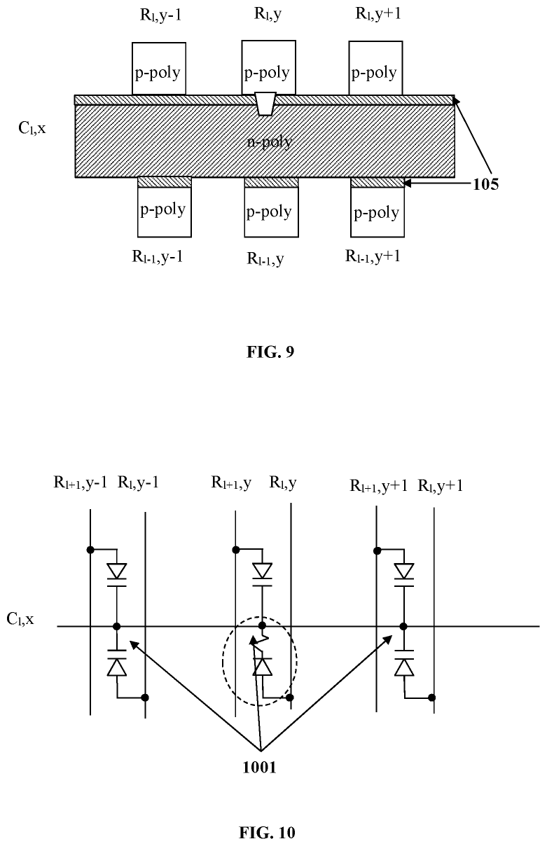

FIG. 9 exemplarily illustrates a partial side elevation view of an embodiment of the multi-layer one time programmable (OTP) permanent memory unit 100 exemplarily illustrated in FIG. 2. In this embodiment, column (Cl,x) of a layer or an OTP permanent memory module is positioned between rows (Rl,y−1), (Rl,y), and (Rl,y+1) of the same layer and bottom rows (Rl−1,y−1), (Rl−1,y), and (Rl−1,y+1) of a bottom layer. The row (Rl,y) indicates a row of a layer one (1) whose index is y. Similarly, (Rl,y−1) and (Rl,y+1) are two rows on either side of the row (Rl,y). As exemplarily illustrated in FIG. 9, the rows of the top and bottom layers are made of a p-type semiconductor material, for example, positive doped polycrystalline silicon (p-poly), while the columns of the layer are made of an n-type semiconductor material, for example, negative doped polycrystalline silicon (n-poly). The column (Cl,x) of the layer intersects the rows (Rl,y−1), (Rl,y), (Rl,y+1) (Rl−1,y−1), (Rl−1,y), and (Rl−1,y+1) with the insulating dielectric material 105 at the intersections. On applying a programming voltage, the insulating dielectric material 105 at the intersections of the column (Cl,x) and the row (Rl,y) breaks down and forms p-n junction diodes at the intersections of the rows and columns of the layer. The p-poly material and the n-poly material diffuse through the broken insulating dielectric material 105 to form the p-n junction diodes.

FIG. 10 exemplarily illustrates a circuit diagram of a memory array circuit of the embodiment of the multi-layer one time programmable (OTP) permanent memory unit shown in FIG. 9. The circuit diagram shows p-n junction diodes 1001 formed at the intersections of each of the rows (Rl,y−1), (Rl,y), (Rl,y+1) (Rl−1,y−1), (Rl−1,y), and (Rl−1,y+1) with the column (Cl,x) due to breaking of the insulating dielectric material 105 at the intersection as disclosed in the detailed description of FIG. 9.

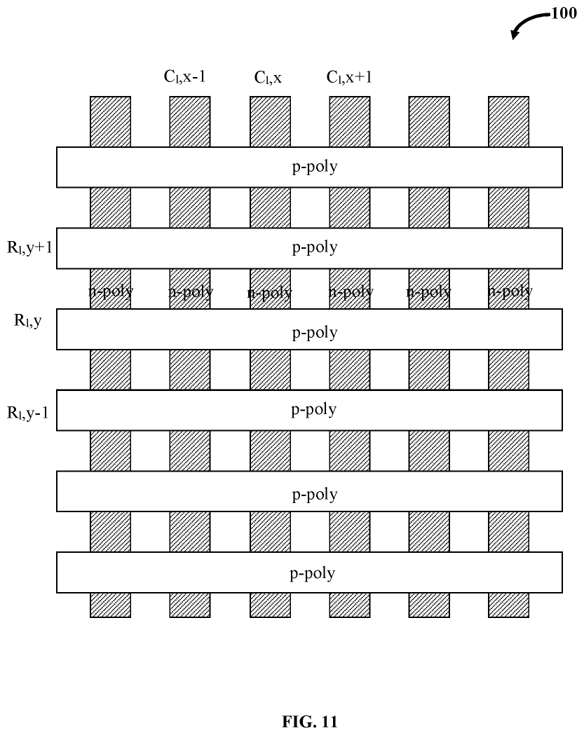

FIG. 11 exemplarily illustrates a top plan view of the multi-layer one time programmable (OTP) permanent memory unit 100. As exemplarily illustrated in FIG. 11, the columns are made of an n-type semiconductor material, for example, negativedoped polycrystalline silicon (n-poly), and the rows are made of a p-type semiconductor material, for example, positive doped polycrystalline silicon (p-poly). In an embodiment (not shown), the columns are made of p-poly and the rows are made of n-poly. The rows of an OTP permanent memory module intersect with the columns of the OTP permanent memory module forming OTP permanent memory units at the intersections of the rows and the columns. The (Cl,x) indicates a column of a layer 1 whose index is x. Similarly, (Cl,x−1) and (Cl,x+1) are two columns on either side of the column (Cl,x). The row (Rl,y) indicates a row of a layer 1 whose index is y. Similarly, (Rl,y−1) and (Rl,y+1) are two rows on either side of the row (Rl,y).

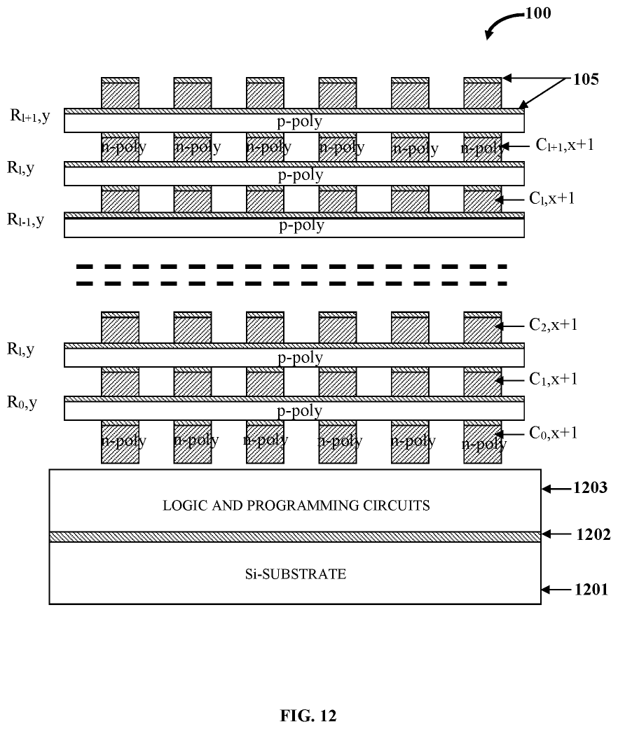

FIG. 12 exemplarily illustrates a front elevation view showing multiple one time programmable (OTP) permanent memory modules stacked in a bottom up direction to form the multi-layer OTP permanent memory unit 100. In the OTP permanent memory modules exemplarily illustrated in FIG. 12, the columns are positioned below the rows to form the multi-layer OTP permanent memory unit 100. The front elevation view exemplarily illustrated in FIG. 12, shows intersections of rows of multiple OTP permanent memory modules with columns of multiple OTP permanent memory modules. The layer one (1) with (R1,y) rows and (C1,x) columns is stacked over layer 0 with (R0,y) rows and (C0,x) columns. Similarly, the layer “l+1” with (Rl+1,y) rows and (Cl+1,x) columns is symmetrically stacked over layer 1 with (R1,y) rows and (C1,x) columns and so on, to obtain the multi-layer OTP permanent memory unit 100.

Stacking rows made of a p-type semiconductor material on top of columns made of an n-type semiconductor material and stacking columns on top of the rows results in a symmetrical arrangement of row/column/row/column, that is, P/N/P/N. Therefore, to increase one more layer in the one time programmable (OTP) permanent memory unit 100, one more layer of each of a thin insulating dielectric material 105 and a counter doped semiconductor material, for example, polycrystalline silicon need to be increased. This increase in one more layer of each of the thin insulating dielectric material 105 and the counter doped semiconductor material in the OTP permanent memory unit 100 creates a new OTP permanent memory module. The stacking of the layers, that is, the OTP permanent memory modules is performed on a silicon (Si) substrate 1201 with a gate oxide 1202 deposited as an insulating dielectric layer. Logic and programming circuits 1203 are used to program the programming voltage to break the insulating dielectric material 105 at the intersections of the rows and the columns of the OTP permanent memory modules of the multi-layer OTP permanent memory unit 100. For example, during programming or reading of the multi-layer OTP permanent memory unit 100, a positive voltage is delivered to the selected rows of a layer and the selected columns of the layer, so that the current can flow from the row made up of the p-type semiconductor material to the column made up of the n-type semiconductor material, resulting in positive p-n junction conduction.

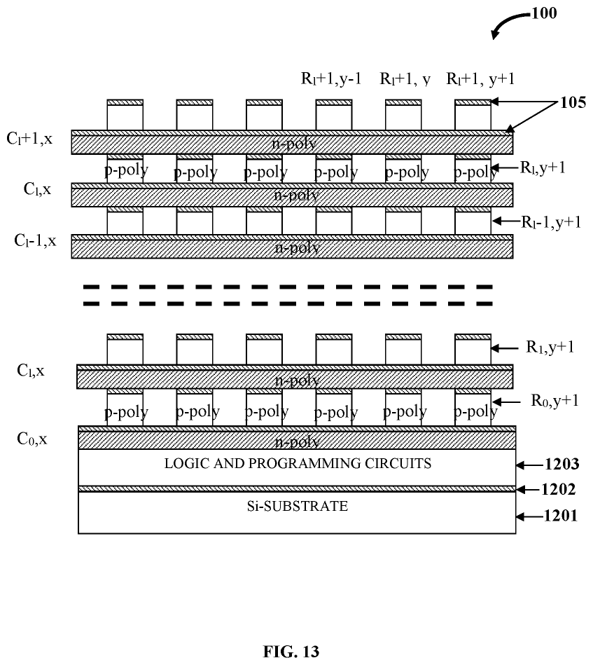

FIG. 13 exemplarily illustrates a side elevation view showing an embodiment of one time programmable (OTP) permanent memory modules stacked in a bottom up direction to form the multi-layer OTP permanent memory unit 100. In the OTP permanent memory modules exemplarily illustrated in FIG. 13, the columns are positioned below the rows to form the multi-layer OTP permanent memory unit 100. The rows and the columns of the OTP permanent memory modules are made of a p-type semiconductor material, for example, a boron doped polycrystalline silicon (p-poly) and an n-type semiconductor material, for example, a phosphor or an arsenic doped polycrystalline silicon (n-poly) respectively. The side elevation view exemplarily illustrated in FIG. 13, shows intersections of rows of multiple OTP permanent memory modules with columns of the OTP permanent memory modules. The layer one (1) with (R₁,y) rows and (Cl,x) columns is stacked over layer 0 with (R₀,y) rows and (C₀,x) columns. Similarly, the layer lower case of L “l”+1, with (Rₗ+1,y) rows and (Cₗ+1,x) columns is stacked over layer “l”, lower case of L, with (Rₗ,y) rows and (Cₗ,x) columns and so on to obtain the multi-layer OTP permanent memory unit 100. The symmetrical stacking of the layers, that is, the OTP permanent memory modules is performed on a silicon substrate 1201 with a gate oxide 1202 deposited as an insulating dielectric layer. Logic and programming circuits 1203 are used to program the programming voltage to break the insulating dielectric material 105 at the intersections of the rows and the columns of the OTP permanent memory modules of the multi-layer OTP permanent memory unit 100.

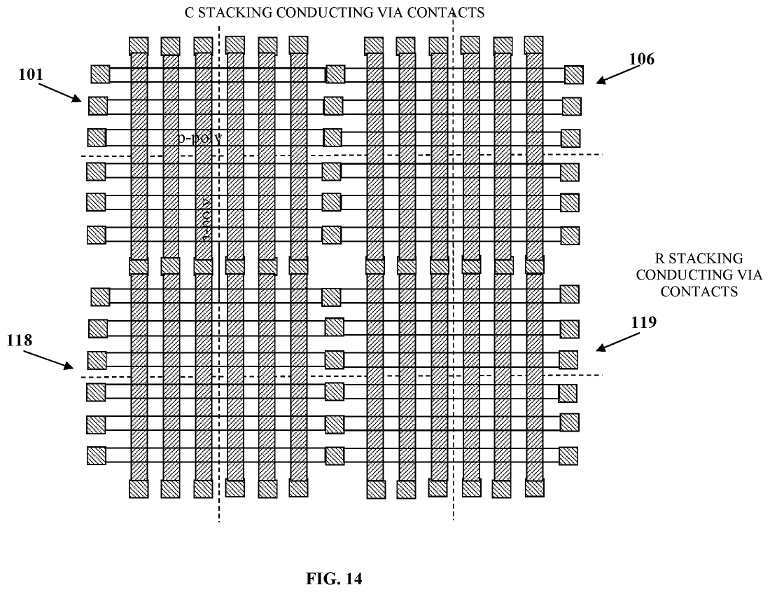

FIG. 14 exemplarily illustrates a top plan view of an embodiment showing multiple one time programmable (OTP) permanent memory modules 101, 106, 118, and 119 positioned adjacent to each other in a single layer, where rows and columns made of counter doped semiconductor materials are interconnected using conducting vias, for example, metal or doped poly vias. The rows and the columns of the OTP permanent memory modules, for example, 101 and 118 are interconnected to the rows and the columns of the adjacent OTP permanent memory modules, for example, 106 and 119 positioned in the single layer using the conducting vias.

FIG. 15 exemplarily illustrates a cross-sectional view of the multi-layer one time programmable (OTP) permanent memory unit, along with a row direction, showing interconnections of rows of doped semiconductor materials, for example, p-type semiconductor materials of different layers stacked to form the multi-layer OTP permanent memory unit. Conducting vias 1501 are used to interconnect rows of the different layers stacked to form the multi-layer OTP permanent memory unit.

FIG. 16 exemplarily illustrates a cross-sectional view of the multi-layer one time programmable (OTP) permanent memory unit along with a column direction, showing interconnections of columns of counter doped semiconductor materials, for example, n-type semiconductor materials of different layers stacked to form the multi-layer OTP permanent memory unit. Conducting vias 1501 are used to interconnect columns of the different layers stacked to form the multi-layer OTP permanent memory unit.

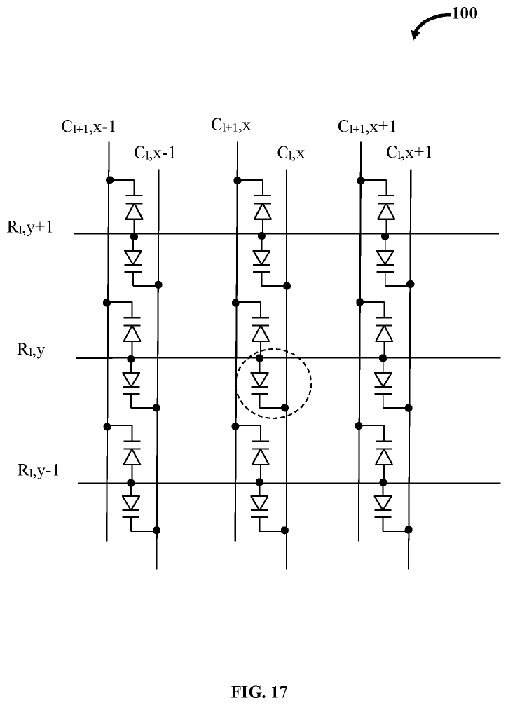

FIGS. 17-19 exemplarily illustrates circuit diagrams of memory array circuits of embodiments of multiple one time programmable (OTP) permanent memory modules stacked to form the multi-layer OTP permanent memory unit 100. FIG. 17 exemplarily illustrates a circuit diagram of a memory array circuit of the multi-layer OTP permanent memory unit 100 showing one layer word lines, that is, rows (Rₗ,y+1), (Rₗ,y) and (Rₗ,y−1) positioned in the same OTP permanent memory module connected to top layer bit lines, that is, columns (Cₗ₊₁,x−1), (Cₗ₊₁,x), and (Cₗ₊₁,x+1) and bottom layer bit lines (Cₗ,x−1), (Cₗ,x), and (Cₗ,x+1). The OTP memory units of the top layer and the bottom layer are connected to the bit lines Cₗ₊₁ and Cₗ and share a common word line Rₗ.

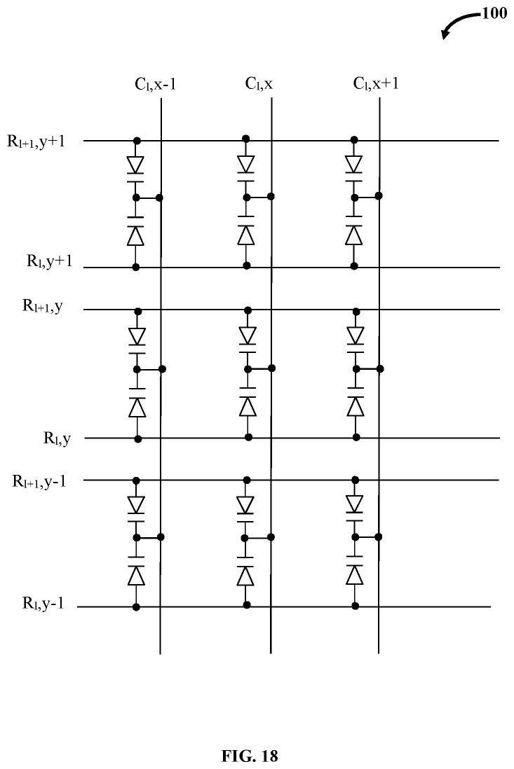

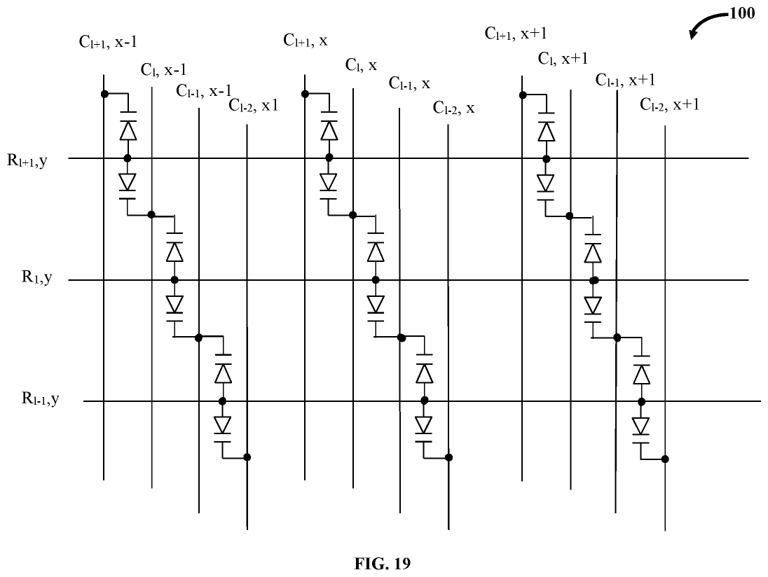

FIG. 18 exemplarily illustrates a circuit diagram of a memory array circuit of the multi-layer OTP permanent memory unit 100, showing one layer columns (Cₗ,x−1), (Cₗ,x), and (Cₗ,x+1) connected to an adjacent top layer and a bottom layer of rows (Rₗ₊₁,y+1), (Rₗ,y+1), (Rₗ₊₁,y−1), (Rₗ,y), (Rₗ₊₁,y−1), and (Rₗ,y−1). The OTP memory units formed on the top layer Rₗ₊₁ and the OTP memory units formed on the bottom layer Rₗ share the same bit lines Cₗ.

FIG. 19 exemplarily illustrates a circuit diagram of a memory array circuit of the multi-layer OTP permanent memory unit 100, showing rows of three layers (Rₗ₊₁, y), (Rₗ,y), and (Rₗ₋₁,y) connected to adjacent columns of four layers, that is, top layer columns (Cₗ₊₁,x−1), (Cₗ₊₁,x), and (Cₗ₊₁,x+1), middle top layer columns (Cₗ,x−1), (Cₗ,x), and (Cₗ,x+1), bottom top layer columns (Cₗ₋₁,x−1), (Cₗ₋₁,x), and (Cₗ₋₁,x+1), and bottom layer columns (Cₗ₋₂,x−1), (Cₗ₋₂,x), and (Cₗ₋₂,x+1).

The multi-layer one time programmable (OTP) permanent memory unit 100 further comprises multi-stage decoder circuits (not shown) implemented in at least two of the M rows 102 or 107 and at least two of the N columns 103 or 108 of the OTP permanent memory modules 101 and 106 exemplarily illustrated in FIG. 2. The multi-stage decoder circuits are shareable across the OTP permanent memory modules 101 and 106 positioned one above another. A multi-layer memory array typically comprises multi-stage decoders, for example, layer decoders, section decoders, row decoders, column decoders, etc. The multi-layer OTP permanent memory unit 100 comprising multiple rows 102 and 107 and columns 103 and 108 employs a multi-stage decoder system, for example, a layer decoder, a page decoder, a section decoder, a row decoder, and a column decoder for decoding the addresses of the rows 102 and 107 and the columns 103 and 108 to allow a programmer and/or reader system to access data stored in the multi-layer OTP permanent memory unit 100.

Table 1 to Table 4 below exemplarily illustrate voltage operation tables of the multi-layer one time programmable (OTP) permanent memory unit 100 exemplarily illustrated in FIG. 2. A voltage operation table enables a user to program and/or read data stored at a location defined by a row (Rₗ) and a column (Cₗ) in the multi-layer OTP permanent memory unit 100. A programming voltage (Vpp), a half programming voltage (Vphf), and a reading voltage (Vrd) are selected to meet process, electrical, and reliability requirements of the multi-layer OTP permanent memory unit 100. The user can program and/or read the data from the multi-layer OTP permanent memory unit 100 by assigning different voltages to a selected row (SR), an unselected row (UR), a selected column (SC), and an unselected column (UC) in the row line (Rₗ) and the column line (Cₗ) respectively, as exemplarily illustrated in Table 1 to Table 4. During the programming, Vphf (½ Vpp) on the unselected rows and the unselected columns is used to reduce voltage stress, thereby avoiding unwanted programming or an oxide reliability problem. Furthermore, the voltage in Rₗ and/or Cₗ can be charged to voltage Vphf and allowed to float represented by Vphf & Float.

TABLE 1
Voltage Operation

| | | R₁ | C₁ |
|---|---|---|---|
| Programming | SR/SC | Vpp | 0 |
| | SR/UC | Vpp | >Vphf & Float |
| | UR/SC | 0 | 0 |
| | UR/UC | 0 | >Vphf & Float |
| Read | SR/SC | Vrd | Sensing |
| | SR/UC | Vrd | Vrd |
| | UR/SC | 0 | Sensing |
| | UR/UC | 0 | Vrd |

Table 1 above exemplarily illustrates a voltage operation table of the multi-layer one time programmable (OTP) permanent memory unit 100 exemplarily illustrated in FIG. 2, and the memory array circuits exemplarily illustrated in FIG. 8, FIG. 10, and FIGS. 17-19, according to option 1. A user can program the OTP memory units of a selected row (SR) and/or a selected column (SC) of the multi-layer OTP permanent memory unit 100 by setting a voltage of a row line (Rₗ) to a programming voltage (Vpp) and a voltage of a column line (Cₗ) to a value zero. The user can non-program the unselected OTP memory units of the SR and/or an unselected column (UC) by setting a voltage of Rₗ to Vpp and a voltage of Cₗ to a half programming voltage (Vphf) and letting the voltage float represented by Vphf&Float. The user can program the unselected row (UR) and/or the SC by setting a voltage of Rₗ to zero and a voltage of Cₗ to zero. The user can program the UR and/or the UC by setting a voltage of Rₗ to zero and a voltage of Cₗ to Vphf&Float. Similarly, the user can read the SR and/or the SC by setting a voltage of Rₗ to a circuit read voltage (Vrd) and by connecting Cₗ to a sensing circuit. The user can read the SR and/or the UC by setting a voltage of Rₗ to Vrd and a voltage of Cₗ to Vrd. The user can read the UR and/or the SC by setting a voltage of Rₗ to zero and by connecting Cₗ to a sensing circuit. The user can read the UR and/or the UC by setting a voltage of Rₗ to zero and a voltage of Cₗ to Vrd.

TABLE 2
Voltage Operation

| | | R₁ | C₁ |
|---|---|---|---|
| Programming | SR/SC | 0 | Vpp |
| | SR/UC | 0 | 0 |
| | UR/SC | >Vphf & Float | Vpp |
| | UR/UC | >Vphf & Float | 0 |
| Read | SR/SC | Vrd | Sensing |
| | SR/UC | Vrd | Vrd |
| | UR/SC | 0 | Sensing |
| | UR/UC | 0 | Vrd |

Table 2 above exemplarily illustrates a voltage operation table of the multi-layer one time programmable (OTP) permanent memory unit 100 exemplarily illustrated in FIG. 2, and the memory array circuits exemplarily illustrated in FIG. 8, FIG. 10, and FIGS. 17-19, according to option 2. A user can program the OTP memory units of a selected row (SR) and/or a selected column (SC) of the multi-layer OTP permanent memory unit 100 by setting a voltage of a row line (Rₗ) to zero and a voltage of a column line to a programming voltage (Vpp). The user can non-program the unselected OTP memory units of the SR and/or the unselected column (UC) by setting a voltage of Rₗ to zero and a voltage of Cₗ to zero. The user can program the unselected row (UR) and/or the SC by setting a voltage of Rₗ to a half programming voltage (Vphf) and letting the voltage float represented by Vphf & Float and a voltage of Cₗ to Vpp. The user can program the UR and/or the UC by setting a voltage of Rₗ to Vphf & Float and a voltage of Cₗ to zero. Similarly, the user can read the SR and/or the SC by setting a voltage of Rₗ to a reading voltage (Vrd) and by connecting Cₗ to a sensing circuit. The user can read the SR and/or the UC by setting a voltage of Rₗ to Vrd and a voltage of Cₗ to Vrd. The user can read the UR and/or the SC by setting a voltage of Rₗ to zero and by connecting Cₗ to a sensing circuit. The user can read the UR and/or the UC by setting a voltage of Rₗ to zero and a voltage of Cₗ to Vrd.

TABLE 3
Voltage Operation

| | | R₁ | C₁ |
|---|---|---|---|
| Programming | SR/SC | Vphf | −Vphf |
| | SR/UC | Vphf | Float |
| | UR/SC | 0 | −Vphf |
| | UR/UC | 0 | Float |
| Read | SR/SC | Vrd | Sensing |
| | SR/UC | Vrd | Vrd |
| | UR/SC | 0 | 0 |
| | UR/UC | 0 | Vrd |

Table 3 above exemplarily illustrates a voltage operation table of the multi-layer one time programmable (OTP) permanent memory unit 100 exemplarily illustrated in FIG. 2, and the memory array circuits exemplarily illustrated in FIG. 8, FIG. 10, and FIGS. 17-19, according to option 3. A user can program the OTP memory units of a selected row (SR) and/or a selected column (SC) of the multi-layer OTP permanent memory unit 100 by setting a voltage of a row line (Rₗ) to a half programming voltage (Vphf) and a voltage of a column line to a negative Vphf. The user can non-program the unselected OTP memory units of the SR and/or the unselected column (UC) by setting a voltage of Rₗ to Vphf and a voltage of Cₗ to Float. The user can program the unselected row (UR) and/or the SC by setting a voltage of Rₗ to zero and a voltage of Cₗ to negative Vphf. The user can program the UR and/or the UC by setting a voltage of Rₗ to zero and a voltage of Cₗ to Float. Similarly, the user can read the SR and/or the SC by setting a voltage of Rₗ to a reading voltage (Vrd) and by connecting Cₗ to a sensing circuit. The user can read the SR and/or the UC by setting a voltage of Rₗ to Vrd and a voltage of Cₗ to Vrd. The user can read the UR and/or the SC by setting a voltage of Rₗ to zero and a voltage of Cₗ to zero. The user can read the UR and/or the UC by setting a voltage of Rₗ to zero and a voltage of Cₗ to Vrd.

TABLE 4
Voltage Operation

| | | R₁ | C₁ |
|---|---|---|---|
| Programming | SR/SC | −Vphf | Vphf |
| | SR/UC | −Vphf | Float |
| | UR/SC | 0 | −Vphf |
| | UR/UC | 0 | Float |
| Read | SR/SC | Vrd | Sensing |
| | SR/UC | Vrd | Vrd |
| | UR/SC | 0 | Sensing |
| | UR/UC | 0 | Vrd |

Table 4 above exemplarily illustrates a voltage operation table of the multi-layer one time programmable (OTP) permanent memory unit 100 exemplarily illustrated in FIG. 2, and the memory array circuits exemplarily illustrated in FIG. 8, FIG. 10, and FIGS. 17-19, according to option 4. A user can program the OTP memory units of a selected row (SR) and/or a selected column (SC) of the multi-layer OTP permanent memory unit 100 by setting a voltage of a row line (Rₗ) to a negative half programming voltage (−Vphf) and a voltage of a column line (Cₗ) to Vphf. The user can non-program the unselected OTP memory units of the SR and/or the unselected column (UC) by setting a voltage of Rₗ to negative Vphf and a voltage of Cₗ to Float. The user can program the unselected row (UR) and/or the SC by setting a voltage of Into zero and a voltage of Cₗ to negative Vphf. The user can program the UR and/or the UC by setting a voltage of Rₗ to zero and a voltage of Cₗ to Float. Similarly, the user can read the SR and/or the SC by setting a voltage of Rₗ to a reading voltage (Vrd) and by connecting Cₗ to a sensing circuit. The user can read the SR and/or the UC by setting a voltage of Rₗ to Vrd and a voltage of Cₗ to Vrd. The user can read the UR and/or the SC by setting a voltage of Rₗ to zero and by connecting Cₗ to a sensing circuit. The user can read the UR and/or the UC by setting a voltage of Rₗ to zero and a voltage of Cₗ to Vrd. In an embodiment, the sensing circuits are connected to row lines instead of column lines.

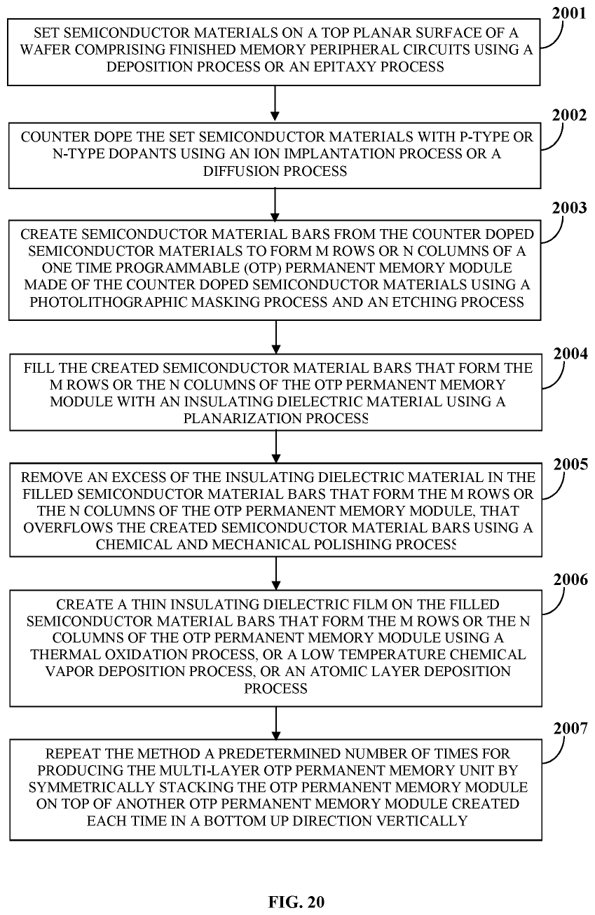

FIG. 20 illustrates a method for manufacturing a multi-layer one time programmable (OTP) permanent memory unit 100 exemplarily illustrated in FIG. 2, using a planar deposition process and a semiconductor material etching process. In the method disclosed herein, semiconductor materials, for example, polycrystalline silicon, silicon, etc., are set 2001 on a top planar surface of a wafer comprising finished memory peripheral circuits, using a deposition process or an epitaxy process. Memory peripheral circuits provide modes of access to the multi-layer OTP permanent memory unit 100. The set semiconductor materials are counter doped 2002 with p-type or n-type dopants using an ion implantation process or a diffusion process. Semiconductor material bars are created 2003 from the counter doped semiconductor materials to form M rows 102 or N columns 103 of an OTP permanent memory module 101 exemplarily illustrated in FIG. 2, made of the counter doped semiconductor materials by removing an excess portion of the counter doped semiconductor materials using a photolithographic masking process and an etching process, where M and N are positive integers greater than one. The OTP permanent memory module 101 constitutes one layer of the multi-layer OTP permanent memory unit 100. The created semiconductor material bars that form M rows 102 of the OTP permanent memory module 101 or the created semiconductor material bars that form N columns 103 of the OTP permanent memory module 101 are filled 2004 with an insulating dielectric material 105 using a planarization process. An excess of the insulating dielectric material 105 that overflows or is higher than the created semiconductor material bars of M rows 102 or the created semiconductor material bars of N columns 103 is removed 2005 from the filled semiconductor material bars that form the M rows 102 or the filled semiconductor material bars that form the N columns 103 using a chemical and mechanical polishing process. A thin insulating dielectric film is created 2006 on top of the filled semiconductor material bars that form the M rows 102 or the N columns 103 of the OTP permanent memory module 101 using a thermal oxidation process, or a low temperature chemical vapor deposition process, or an atomic layer deposition (ALD) process. The method disclosed above is repeated 2007 a predetermined number of times for producing the multi-layer OTP permanent memory unit 100 by symmetrically stacking the OTP permanent memory module, for example, 106 created at each time in a bottom up direction vertically as exemplarily illustrated in FIG. 2. Multiple OTP memory units, for example, 111a, 111b, 111c, and 111d exemplarily illustrated in FIG. 6, are formed at intersections 104 of the M rows 102 or the N columns 103 of the OTP permanent memory module 101 and intersections 110 between the OTP permanent memory module 101 and another OTP permanent memory module 106 positioned one above the other. The OTP memory units, for example, 111a, 111b, 111c, and 111d in the multi-layer OTP permanent memory unit 100 can be increased by iteratively creating another thin insulating dielectric film on the topmost OTP permanent memory module 106 and stacking the M rows or the N columns made of a counter doped semiconductor material on the iteratively created thin insulating dielectric film, where the counter doped semiconductor material is a p-type semiconductor material or an n-type semiconductor material.

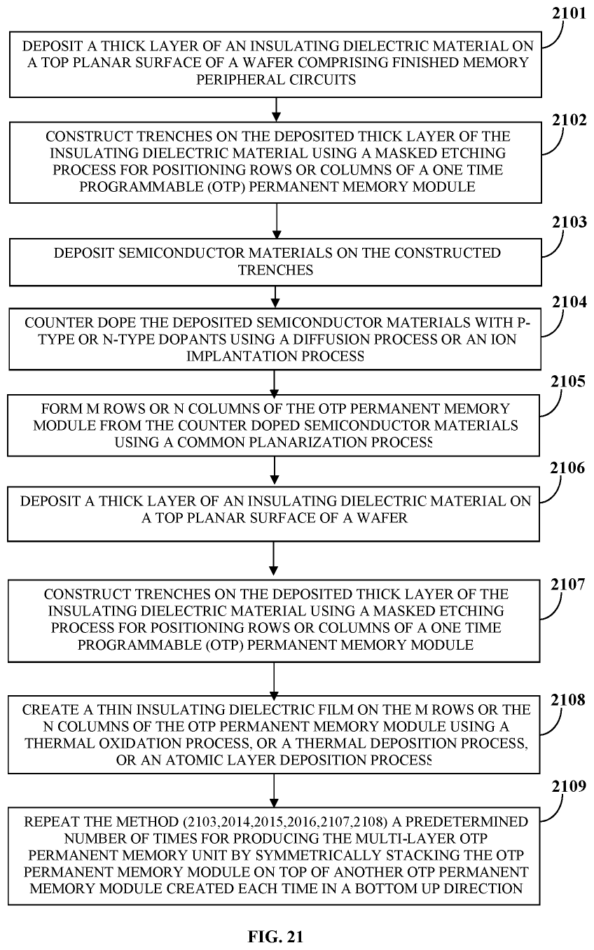

FIG. 21 illustrates a method for manufacturing a multi-layer one time programmable (OTP) permanent memory unit 100 exemplarily illustrated in FIG. 2, by constructing trenches in an insulating dielectric material and filling the trenches with semiconductor materials. In the method disclosed herein, a thick layer of the insulating dielectric material is deposited 2101 on a top planar surface of a wafer comprising finished memory peripheral circuits. Trenches are constructed 2102 on the deposited thick layer of the insulating dielectric material using a masked etching process for positioning rows or columns of an OTP permanent memory module. Semiconductor materials are deposited 2103 on the constructed trenches. The deposited semiconductor materials are counter doped 2104 with p-type or n-type dopants using a diffusion process or an ion implantation process. In an embodiment, an in-situ deposition method is used to achieve high concentration doping, wherein steps 2103 and 2104 are combined as a single step. M rows 102 or N columns 103 of the OTP permanent memory module 101 are formed 2105 from the counter doped semiconductor materials by removing an excess of the deposited semiconductor materials from the counter doped semiconductor materials using a common planarization process, where M and N are positive integers greater than one. Then, a thick layer of the insulating dielectric material is deposited 2106 on a top planar surface of the wafer. Trenches are constructed 2107 on the deposited thick layer of the insulating dielectric material using a masked etching process for positioning rows or columns of an OTP permanent memory module. The etching process will stop till reaching the last deposited semiconductor materials. A thin insulating dielectric film is created 2108 on the M rows 102 or the N columns 103 of the OTP permanent memory module 101 using a thermal oxidation process, or a thermal deposition process, or an atomic layer deposition (ALD) process. The thin insulating dielectric film exemplarily illustrated in FIG. 2, on the M rows 102 or the N columns 103 of the OTP permanent memory module 101 serves as a programmable dielectric material. The method disclosed 2103, 2104, 2105, 2106, 2107 and 2108 above is repeated 2109 a predetermined number of times for producing the multi-layer OTP permanent memory unit 100 by symmetrically stacking the OTP permanent memory module, for example, 106 created at each time in a bottom up direction vertically as exemplarily illustrated in FIG. 2. OTP memory units, for example, 111a, 111b, 111c, and 111d exemplarily illustrated in FIG. 6, are formed and can be increased in the multi-layer OTP permanent memory unit 100 as disclosed in the detailed description of FIG. 20.

An example of a Schottky contact:

A multi-layer, one-time programmable permanent memory unit containing: At least two layers of one-time programmable permanent memory modules, one layer stacked on top of another layer; each of the at least two layers of one-time programmable permanent memory modules comprising M row lines and N column lines, wherein M and N are greater than 1 positive integer;

At each intersection, the material of row line M and column line N are respectively required to conform to the two materials required to create a Schottky contact at the intersection, for example, the row line material is available and forms a Schottky tube. Metals such as Al, Ag, Au, Pt, and columnar N materials are N-type semiconductor materials such as N-Poly, N—Si, N-IZO (N-type indium zinc oxide) and the like. Between the material intersections of row line M and column line N is a thin medium such as SiO 2 or other material that can be used for the antifuse mentioned in this patent application.

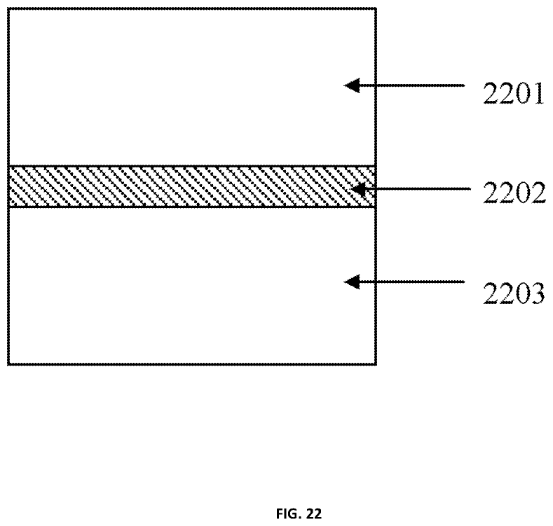

Specifically, for the intersection of a particular row and column line, the structure is “row line material—insulating medium—column line material”, and the foregoing “row line and column line materials are respectively in accordance with the intersection The two materials required to create a Schottky contact at the point means that the line material and the line material should be capable of forming a Schottky contact in the event of breakdown of the dielectric. FIG. 22 shows the structure. Wherein, 2201 is a metal that can be used to form a Schottky contact, such as Al, Ag, Au, Pt, 2202 is a thin dielectric layer, and 2203 is an N-type semiconductor material, such as N-Poly, N—Si, N-IZO (N Type indium zinc oxide).

The foregoing examples have been provided merely for the purpose of explanation and are in no way to be construed as limiting of the multi-layer one time programmable (OTP) permanent memory unit 100 exemplarily illustrated in FIG. 2, and the methods disclosed herein. While the multi-layer OTP permanent memory unit 100 and the methods have been described with reference to various embodiments, it is understood that the words, which have been used herein, are words of description and illustration, rather than words of limitation. Furthermore, although the multi-layer OTP permanent memory unit 100 and the methods have been described herein with reference to particular means, materials, and embodiments, the multi-layer OTP permanent memory unit 100 and the methods are not intended to be limited to the particulars disclosed herein; rather, the multi-layer OTP permanent memory unit 100 and the methods extend to all functionally equivalent structures, methods and uses, such as are within the scope of the appended claims. Those skilled in the art, having the benefit of the teachings of this specification, may effect numerous modifications thereto and changes may be made without departing from the scope and spirit of the multi-layer OTP permanent memory unit 100 and the methods disclosed herein in their aspects.

I claim:

1. A multi-layer one time programmable permanent memory unit comprising:
at least two one time programmable permanent memory modules stacked in layers one above another, wherein each of said at least two one time programmable permanent memory modules comprises M rows and N columns made of counter doped semiconductor materials, wherein M and N are positive integers greater than one; and
a thin insulating dielectric material positioned at intersections of and between said M rows and said N columns of said each of said at least two one time programmable permanent memory modules and on one of a top surface and a bottom surface of each of said M rows and each of said N columns of said each of said at least two one time programmable permanent memory modules.

2. The multi-layer one time programmable permanent memory unit of claim 1, wherein said each of said at least two one time programmable permanent memory modules is stacked in a bottom up direction by connecting said intersections of said M rows and said N columns of said each of said at least two one time programmable permanent memory modules with intersections between said at least two one time programmable permanent memory modules, wherein said M rows of said each of said at least two one time programmable permanent memory modules are positioned on one of a top and a bottom of said N columns.

3. The multi-layer one time programmable permanent memory unit of claim 1, further comprising a plurality of one time programmable memory units formed at said intersections of said M rows and said N columns of said each of said at least two one time programmable permanent memory modules and intersections between said at least two one time programmable permanent memory modules.

4. The multi-layer one time programmable permanent memory unit of claim 3, wherein each of said one time programmable memory units comprises a p-type semiconductor area, an n-type semiconductor area, and a thin insulating dielectric area positioned between said p-type semiconductor area and said n-type semiconductor area.

5. The multi-layer one time programmable permanent memory unit of claim 4, wherein said each of said one time programmable memory units further comprises at least two connecting terminals positioned on said p-type semiconductor area and said n-type semiconductor area of said each of said one time programmable memory units.

6. The multi-layer one time programmable permanent memory unit of claim 5, wherein said at least two connecting terminals of said each of said one time programmable memory units are connected to each other using conducting vias.

7. The multi-layer one time programmable permanent memory unit of claim 4, wherein thickness of said thin insulating dielectric material forming said thin insulating dielectric area of said each of said one time programmable memory units has a preset value corresponding to a breakdown voltage of said each of said one time programmable memory units.

8. The multi-layer one time programmable permanent memory unit of claim 1, further comprising multi-stage decoder circuits implemented in at least two of said M rows and at least two of said N columns of said at least two one time programmable permanent memory modules, wherein said multi-stage decoder circuits are shareable across said at least two one time programmable permanent memory modules positioned one above another.

9. The multi-layer one time programmable permanent memory unit of claim 1, wherein said M rows of said each of said at least two one time programmable permanent memory modules is made of one of a p-type semiconductor material and an n-type semiconductor material, and wherein said N columns of said each of said at least two one time programmable permanent memory modules is made of a counter one of said p-type semiconductor material and said n-type semiconductor material.

10. A multi-layer one time programmable permanent memory unit comprising:
at least two one time programmable permanent memory modules stacked in layers one above another, wherein each of said at least two one time programmable permanent memory modules comprises M rows and N columns made of conductors, wherein M and N are positive integers greater than one; and
a plurality of one time programmable memory units formed at intersections of said M rows and said N columns of said each of said at least two one time programmable permanent memory modules and intersections between said at least two one time programmable permanent memory modules.

11. A method for manufacturing a multi-layer one time programmable permanent memory unit, said method comprising:
setting semiconductor materials on a top planar surface of a wafer comprising finished memory peripheral circuits using one of a deposition process and an epitaxy process;
counter doping said set semiconductor materials with dopants using one of an ion implantation process and a diffusion process, wherein said dopants comprise one of p-type dopants and n-type dopants;
creating semiconductor material bars from said counter doped semiconductor materials to form one of M rows and N columns of a one time programmable permanent memory module made of said counter doped semiconductor materials by removing an excess portion of said counter doped semiconductor materials using a photolithographic masking process and an etching process, where M and N are positive integers greater than one;
filling said created semiconductor material bars that form said one of said M rows and said N columns of said one time programmable permanent memory module with an insulating dielectric material using a planarization process;
removing an excess of said insulating dielectric material in said filled semiconductor material bars that form said one of said M rows and said N columns of said one time programmable permanent memory module, that overflows said created semiconductor material bars using a chemical and mechanical polishing process;
creating a thin insulating dielectric film on said filled semiconductor material bars that form said one of said M rows and said N columns of said one time programmable permanent memory module using one of a thermal oxidation process, a low temperature chemical vapor deposition process, and an atomic layer deposition process; and
repeating said method a predetermined number of times for producing said multi-layer one time programmable permanent memory unit by symmetrically stacking said one time programmable permanent memory module created at each of said times in a bottom up direction vertically.

12. The method of claim 11, further comprising forming a plurality of one time programmable memory units at intersections of said M rows and said N columns of said one time programmable permanent memory module and intersections between one said one time programmable permanent memory module and another said one time programmable permanent memory module positioned one above another.

13. The method of claim 12, further comprising increasing said one time programmable memory units in said multi-layer one time programmable permanent memory unit by iteratively creating another said thin insulating dielectric film on a topmost said one time programmable permanent memory module and stacking said one of said M rows and said N columns made of a counter doped semiconductor material on said created another said thin insulating dielectric film, wherein said counter doped semiconductor material is one of a p-type semiconductor material and an n-type semiconductor material.

14. A method for manufacturing a multi-layer one time programmable permanent memory unit, said method comprising:
depositing a thick layer of an insulating dielectric material on a top planar surface of a wafer comprising finished memory peripheral circuits;
constructing trenches on said deposited thick layer of said insulating dielectric material using a masked etching process for positioning one of rows and columns of a one time programmable permanent memory module;
depositing semiconductor materials on said constructed trenches;
counter doping said deposited semiconductor materials with dopants using one of a diffusion process and an ion implantation process, wherein said dopants comprise one of p-type dopants and n-type dopants;
forming one of M rows and N columns of said one time programmable permanent memory module from said counter doped semiconductor materials by removing an excess of said deposited semiconductor materials from said counter doped semiconductor materials using a common planarization process, where M and N are positive integers greater than one;
depositing a thick layer of an insulating dielectric material on a top planar surface of the wafer;
constructing trenches on said deposited thick layer of said insulating dielectric material using a masked etching process for positioning one of rows and columns of a one time programmable permanent memory module; The etching process will stop till reaching the last deposited semiconductor materials;
creating a thin insulating dielectric film on said one of said M rows and said N columns of said one time programmable permanent memory module using one of a thermal oxidation process, a thermal deposition process, and an atomic layer deposition process, wherein said thin insulating dielectric film on said one of said M rows and said N columns of said one time programmable permanent memory module serves as a programmable dielectric material; and
repeating said method a predetermined number of times for producing said multi-layer one time programmable permanent memory unit by symmetrically stacking said one time programmable permanent memory module created at each of said times in a bottom up direction vertically.

15. The method of claim 14, further comprising forming a plurality of one time programmable memory units at intersections of said M rows and said N columns of said one time programmable permanent memory module and intersections between one said one time programmable permanent memory module and another said one time programmable permanent memory module positioned one above another.

16. The method of claim 15, further comprising increasing said one time programmable memory units in said multi-layer one time programmable permanent memory unit by iteratively creating another said thin insulating dielectric film on a topmost said one time programmable permanent memory module and stacking said one of said M rows and said N columns made of a counter doped semiconductor material on said created another said thin insulating dielectric film, wherein said counter doped semiconductor material is one of a p-type semiconductor material and an n-type semiconductor material.

17. The method of claim 16 for creating vertically stacking multi-layer 3D one time programmable (OTP) permanent memory tilted 90 degrees and stacked vertically to form an array of n+ doped polysilicon-oxide electrode pillars as bit-line (BL) stack and p+ doped polysilicon as word-line (WL) planes. The vertical one time programmable (OTP) permanent memory cells are created between the perpendicular n+ polysilicon/oxide pillars and multi-layer plane p+ polysilicon electrodes. Only one critical n+ polysilicon-oxide lithography and deposition step is required.

18. The method of claim 17 for manufacturing the vertical polysilicon-oxide pillars and horizontal polysilicon planes by depositing multiple layers of polysilicon-oxide-polysilicon stacks followed by a hole etching and patterning of electrodes and p+ polysilicon planes.

19. The method of claim 17, an appropriate bias and decoding schemes for word-line (z-direction), bit line (y-direction) and source-line (x-direction) through select transistor schemes and TSV scheme to allow the individual cell access for the 3D one time programmable (OTP) permanent memory array.
